(19) United States
(12) Patent Application Publication
(10) Pub. No.: US 2010/0188818 A1
(43) Pub. Date: Jul. 29, 2010

(54) HEAT DISSIPATING DEVICE AND METHOD OF MANUFACTURING THE SAME

(75) Inventor: Ji Li, Sinjhuang City (TW)

Correspondence Address: NIKOLAI & MERSEREAU, P.A., 900 SECOND AVENUE SOUTH, SUITE 820, MINNEAPOLIS, MN, 55402, US

(73) Assignee: BEIJING AVC TECHNOLOGY RESEARCH CENTER CO., LTD., Wangjing New Industry District (CN)

(21) Appl. No.: 12/470,646

(22) Filed: May 22, 2009

(30) Foreign Application Priority Data
Jan. 23, 2009 (CN) 200910077583.7

(51) Int. Cl. H05K 7/20; F28D 15/02; B21D 53/02

(52) U.S. Cl. 361/700; 165/104.21; 165/104.22; 165/185; 29/890.032

(57) ABSTRACT

A heat dissipating device includes a flat evaporator, a vapor pipe, a liquid pipe, and a condenser. The flat evaporator consists of a bottom plate, a porous material, and a top lid. The porous material is located on the bottom plate and provided with vapor flow passages. The vapor pipe and liquid pipe are communicably connected at respective one end to a vapor port and a liquid port on the evaporator, and at the other end to two sides of the condenser. The evaporator has simple structure and low manufacturing cost, and can fully effectively bear on an electronic chip to enable reduced room needed for installing the evaporator and reduced thermal resistance during heat dissipation. The heat dissipating device can be used to dissipate heat produced by computer chips, and to cool LED illuminating devices, chips for communication devices, high-power heat-producing elements in military, medical, aerial, and aerospace apparatuses.

### FIELD OF THE INVENTION

The present invention relates to a heat dissipating device applicable to elect conic products, and more particularly to a heat dissipating device having a loop heat pipe and to a method of manufacturing the heat dissipating device.

### BACKGROUND OF THE INVENTION

Cooling of high-power electronic chips is a very, important technical aspect in connection with the operation of different electronic, computing, communication, and photo-electric apparatuses. The following are several ways being currently-adopted in the market for dissipating heat produced by high-power electronic devices: (1) employing cooling fans and heat sinks; (2) employing cooling fans, heat pipes and heat sinks; and (3) employing cooling fans and liquid-cooling technology. While these ways, are more or less helpful in solving the problem of heat dissipation, for the high-power electronic devices, they still have some disadvantages. For example, (1) in the case of employing fans and heat sinks to dissipate heat, frequently, area of radiating fins is expanded and rotating speed of the cooling fan is increased for the purpose of enhancing the heat dissipating ability of the heat dissipating device. As a result, noise produced during the operation of the cooling fan is increased at the same time, and the heat dissipating device would become bulky and heavy to not only cause problem in installation thereof but also apply great pressure on the electronic devices; (2) in the case of employing cooling fans, heat pipes and heat sinks to dissipate heat, while the disadvantages in the first way are overcome, the heat dissipating device itself becomes very complicated in structure, the design and installation of heat pipes are frequently subject to practical structural restriction, and the heat dissipating ability is still limited if the number, of heat pipes is low; and (3) in the case of employing liquid cooling techniques to dissipate heat, while the liquid cooling is superior to the above two ways in terms of the heat dissipating performance thereof and therefore has high potential in heat dissipation technical field, the liquid cooling involves extremely complicated mechanisms and requires very high cost. Currently, it is already possible for a performance-optimized small-scale liquid-cooling heat dissipating device to dissipate about 1000 W of heat while the operation noise is also under controlled, and the liquid-cooling heat sink thereof can have an overall thermal resistance lower than 0.12° C./W. However, as having been mentioned above, the liquid-cooling technique involves extremely completed mechanisms. Besides, the increased number of pumps for driving the liquid working medium to flow as well as the lacking of a pipe connecting technique that guarantees absolutely leak-free pipe connection both have adverse influences on the actual usable life of the liquid-cooling heat dissipating device. Further, the liquid-cooling heat dissipating device requires a manufacturing cost about three times as high as that for a general heat-pipe heat dissipating device providing the same heat dissipating ability. Therefore, the cost of the liquid-cooling heat dissipating device is highest among the three different heat dissipation ways.

To overcome the above disadvantages, there is developed a loop heat pipe technique. The loop heat pipe technique is invented in 1974 and has been currently widely applied in the aerial and aerospace fields. In the pest five years, the loop heat pipe technique has gradually been applied in electronic chip heat dissipation. The loop heat pipe combines the advantages of heat-pipe heat dissipation and liquid cooling while avoids the disadvantages of the two heat dissipating techniques. The loop heat pipe provides the same heat dissipation potential as that of the liquid-cooling technique. A compact miniature loop heat pipe can easily dissipate more than 500 W of heat, and has an overall thermal resistance lower than 0.15° C./W. Meanwhile, the loop heat pipe can be manufactured at a cost much lower than that of the liquid-cooling heat dissipating device. The loop-heat-pipe type heat dissipating device also provides the following advantages: (1) its performance is less affected by the force of gravity as compared to general heat pipes; (2) it can have a variety of configurations in design to satisfy different requirements; and (3) it can be used in long-distance heat transfer. Since the loop heat pipe is manufactured through a process similar to that for general heat pipes, the loop heat pipe can have reliability and service life the same as the general heat pipes, and can be widely used in some relatively severe environments.

A conventional loop-heat-pipe type heat dissipating device mainly includes an evaporator having a capillary structure provided therein, vapor pipe and liquid pipe for circulating a working medium therein, and a condenser for releasing heat into ambient environment. When operating, a bottom face of the evaporator receives heat transferred from a heat-producing element, such as an electronic chip, so that the working medium is vaporized in the capillary structure. When the vapor flows through the condenser, heat is released from the vapor to an environmental medium, such as air, that flows through the condenser. Through natural cooling or forced cooling by a cooling fan, the vapor is converted into liquid, which will return to the evaporator via the liquid pipe due to a capillary action provided by the porous material in the evaporator to thereby complete one thermodynamic cycle. The above operation is repeated to constantly release heat from the heat-producing element into ambient air.

Currently, there are not many products and patents that employ loop heat pipe in electronic heat dissipation. Some examples include China Patent Nos. 01259718.X and 200810028106.7. According to the existing patents that relate to the design of an evaporator, the basic structure of most evaporators generally can be divided into the following two types: (1) cylinder type; and (2) flat plate type. The cylinder type evaporator is the basic structure for conventional loop heat pipe, as shown in FIGS. 1A and 1B. Currently, the flat plate type evaporator can be further divided into two types: (a) disk type as shown in FIGS. 1C, 1D and 1E; and (b) flat plate type as shown in FIGS. 1F and 1G, which is formed through micromachining, such as that disclosed in China patent ZL01259718.X.

Basically, most of the electronic chips are square in shape, including a cube or a right cuboid. Thus, the cylinder-type evaporator having a curved surface is not advantageous for contacting with the flat surface of the chip. The disk-type evaporator involves complicated manufacturing process, and would occupy extra space when being installed. Up to date, the heat dissipation performance of the micromachined flat plate type evaporator for the loop heat pipe has not yet reached the requirements for commercial usage.

### SUMMARY OF THE INVENTION

To overcome the disadvantages in the conventional loop heat pipe, a primary object of the present invention is to provide a heat dissipating device and a method of manufacturing the same, so that the heat dissipating device can (1) fully contact with a heat producing electronic chip to efficiently dissipate heat produced by the electronic chip; (2) largely reduce the thermal resistance during heat dissipation; and (3) have an evaporator that occupies only a small space to facilitate miniaturization of the heat dissipating device. The heat dissipating device according to the present invention is structurally simple and reliable for use, and can be manufacturing with simple process at reduced cost, making the present invention more practical for use. Moreover, with the structural design and the manufacturing process of the heat dissipating device according to the present invention, the potential of the loop heat pipe in heat dissipation can be fully developed.

To achieve the above and other objects, the heat dissipating device according to the present invention includes at least an evaporator, a vapor pipe, a liquid pipe, and a condenser. The evaporator is a flat evaporator, which can have a rectangular, polygonal, or any other geometrical shape. The flat evaporator has a main body consisting of a bottom plate, at least one porous material, and a top lid. The porous material is located on the bottom plate, and the top lid can be assembled to the bottom plate. The bottom plate has a flat bottom face for correspondingly bearing on an electronic chip. The porous material is provided with a plurality of vapor flow passages. The top lid is provided at two opposite sides with a vapor port and a liquid port, to which an end of the vapor pipe and the liquid pipe are respectively communicably connected.

The top lid of the flat evaporator is internally provided with a partition, so that a compensating chamber is formed between the partition and the liquid port, and a vapor collecting chamber is formed between the partition and the vapor port, and the partition isolates the compensating chamber from the vapor collecting chamber. The top lid is provided at a location above the compensating chamber with a port, via which the flat evaporator can be evacuated and a working medium can be filled into the evaporator.

To achieve the above and other objects, the method of manufacturing the above-described heat dissipating device according to the present invention includes the following steps:
(a) Prepare the porous material using a metal powder or metal mesh, or an inorganic material, such as ceramic powder, that has high heat conductivity. In the case of preparing the porous material using a metal powder, the metal powder can be independently sintered or directly sintered on the bottom plate. During the sintering process, the sinter powder is filled in a special tool, which can be made of steel or high-temperature ceramic material. The tool has an internal chamber configured corresponding to a desired external geometrical configuration of the porous material. And, a plurality of core rods corresponding to a desired cross sectional shape for the vapor flow passages on the porous material are used along with the tool to form the porous material with desired vapor flow passages. The core rods can be made of graphite or steel. Finally, the whole tool with the sinter powder filled therein is positioned in a sintering furnace. After the sintering process, the tool and the core rods are removed to obtain the porous material. Alternatively, the porous material can be prepared through electronic processing technology or using nanorods;
(b) Prepare the top lid using copper or aluminum or a semiconductor material. In preparing the top lid with a metal material, the top lid can be formed through mechanical machining, or through press casting and followed by mechanical machining. Or, in preparing the top lid with a semiconductor material, the top lid can be formed through microelectronic processing;
(c) Prepare the bottom plate by mechanically machining, stamping, or casting a material with high heat conductivity, such as copper, aluminum, or silicon. Or, the bottom plate can be prepared through microelectronic processing;
(d) Connect the top lid to the bottom plate when the preparation of the porous material is completed, so as to complete the fabrication of the evaporator. In the case of making the top lid and the bottom plate with a metal material, the top lid and the bottom plate can be connected together by soldering or brazing. Or, in the case of making the top lid and the bottom plate with a semiconductor material, the top lid and bottom plate can be connected together through bonding; and
(e) Weld the finished flat evaporator to the pipes that are extended through the condenser. Then, carry on standard heat pipe forming procedures, including cleaning the pipe, evacuating the pipe, filling working medium into the pipe and sealing the pipe, so as to complete the heat dissipating device having a loop heat pipe provided with a flat evaporator.

With the above arrangements, the heat dissipating device of the present invention is superior to conventional heat dissipating devices in view of the following advantages provided, by the present invention:
(1) Providing large and effective contact area with the electronic chip and requiring reduced space for mounting.
   Generally, most of the electronic chips are square in shape. The flat evaporator used in the present invention can be configured to have a rectangular, a polygonal, or any other geometrical shape, and the bottom plate of the flat evaporator for contacting with the electronic chip has a flat bottom face to enable fully bearing of the bottom plate on the fiat surface of the chip. Therefore, the evaporator and the electronic chip can have a large and effective contact area between them to reduce the space needed to mounting the heat dissipating device onto the electronic chip, enabling the electronic device to be miniaturized.
(2) Reducing thermal resistance during heat dissipation.
   The evaporator in the present invention includes a porous material, which has a capillary structure to provide capillary action. By directly sintering the porous; material to the bottom plate of the evaporator, a largely reduced thermal resistance during heat dissipation can be obtained. Meanwhile, the potential of the loop heat pipe in heat dissipation can be fully extended. According to experimental tests conducted by the inventor, the heat dissipating device with loop heat pipe according to the present invention has a low system thermal resistance of 0.15° C./W, and the loop heat pipe itself has a thermal resistance smaller than 0.05° C./W with a heat dissipating ability higher than 600 W.
(3) Having simple and reliable processing method to enable reduced manufacturing cost.
   The top lid and the bottom plate of the evaporator, the port for filling working medium, the liquid pipe, and the vapor pipe can be completed at the same time through welding. Therefore, time and cost for fabricating the heat dissipating device can be reduced.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1A is a schematic view showing the structure of a conventional cylinder type evaporator;

FIG. 1B is a cross-sectional view taken along line A-A of FIG. 1A;

FIG. 1C is a schematic view showing the structure of a conventional disk type evaporator;

FIG. 1D is a cross-sectional view taken along line A-A of FIG. 1C;

FIG. 1E is a cross-sectional view taken along line B-B of FIG. 1C;

FIG. 1F is a schematic view showing the structure of a conventional flat plate type evaporation manufactured through micromachining technology;

FIG. 1G is a cross-sectional view taken along line A-A of FIG. 1F;

FIG. 2 is an assembled perspective view of a heat dissipating device according to a preferred embodiment of the present invention that includes a loop heat pipe with a flat evaporator;

FIG. 3A is an assembled sectional view showing the structure of the flat evaporator in FIG. 2;

FIG. 3B is a cross-sectional view taken along line A-A of FIG. 3A;

FIG. 4 is a perspective view of a bottom plate for the flat evaporator shown in FIG. 3A;

FIG. 5A is a perspective view of a porous material with arch-sectioned vapor flow passages for the flat evaporator in the heat dissipating device of the present invention;

FIG. 5B is a perspective view of a porous material with rectangular-sectioned vapor flow passages for the flat evaporator in the heat dissipating device of the present, invention;

FIG. 5C is a perspective view of a porous material with oval-sectioned vapor flow passages for the flat evaporator in the heat dissipating device of the present invention;

FIG. 5D is a perspective view of a porous material with circular-sectioned vapor flow passages for the flat evaporator in the heat dissipating device of the present, invention;

FIG. 5E shows the manner of forming the porous material for the present invention;

FIG. 6A is top perspective view of a top lid for the flat evaporator used in the present invention;

FIG. 6B is a bottom perspective view of the top lid for the flat evaporator used in the present invention;

FIG. 7 is an exploded perspective view of the flat evaporator used in the present invention; and

FIG. 8 is an exploded perspective view of the heat dissipating device of the present invention.

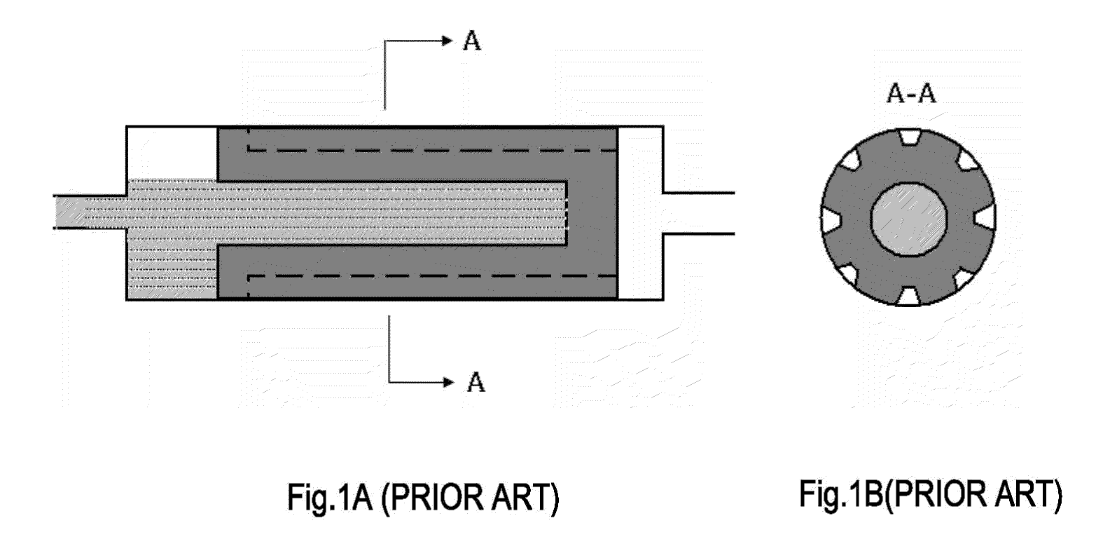

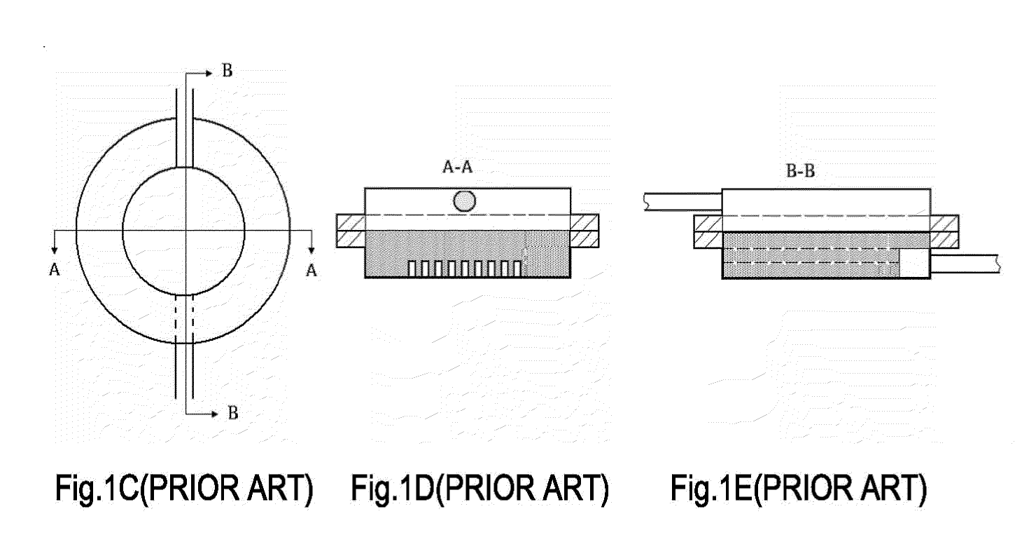

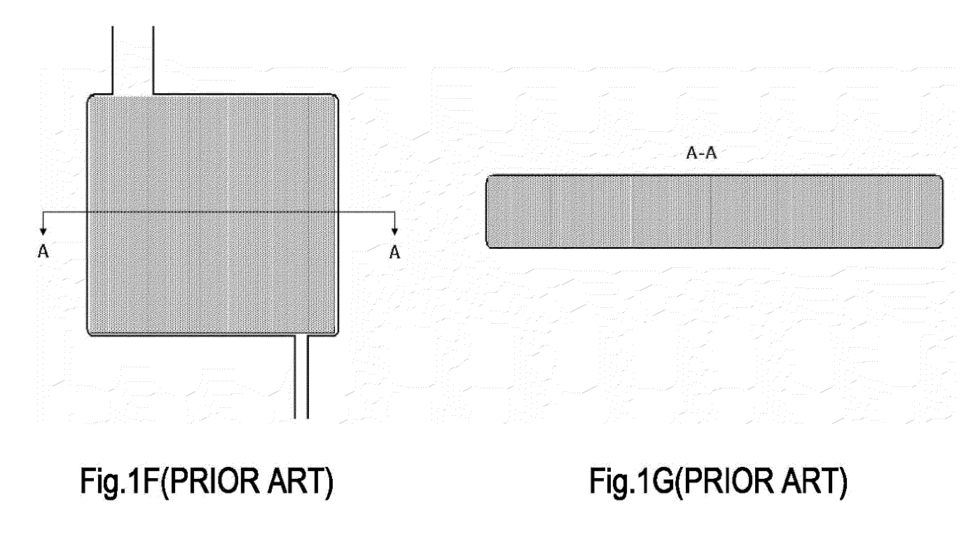

### DETAILED DESCRIPTION OF THE PREFERRED EMBODIMENTS

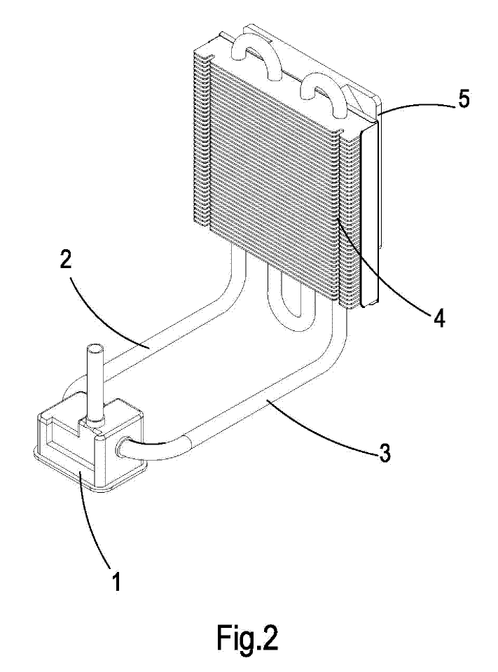

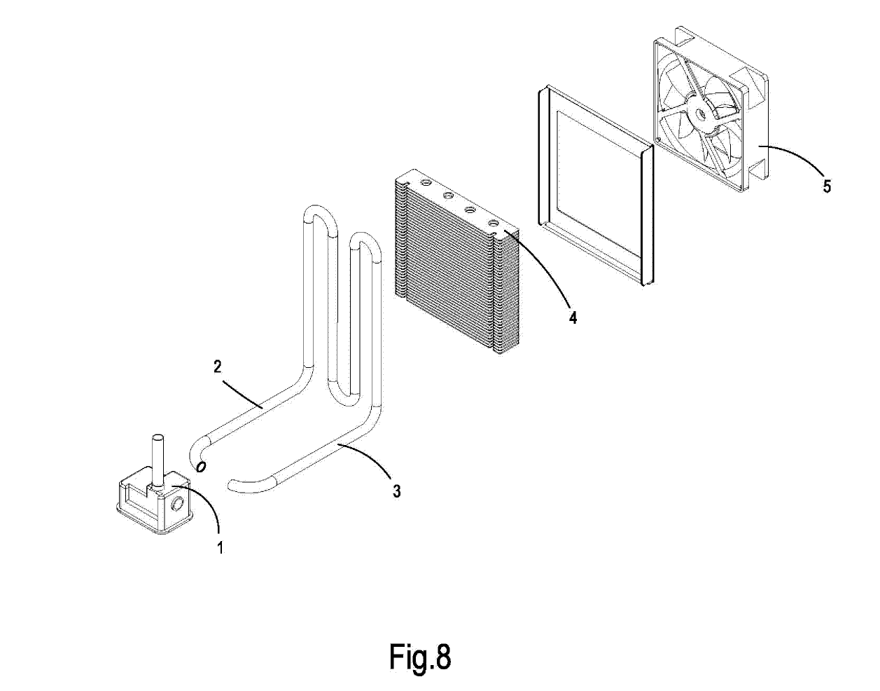

Please refer to FIGS. 2 and 8 that assembled and exploded perspective views, respectively, of a heat dissipating device according to a preferred embodiment of the present invention characterized by having a loop heat pipe with flat evaporator. As shown, the heat dissipating device of the present invention mainly includes a fiat evaporator 1, a vapor pipe 2, a liquid pipe 3, and a condenser 4. A cooling fan 5 can be further mounted to one side face of the condenser 4 for forcing air through the condenser 4. The flat evaporator 1 can have a rectangular shape, a polygonal shape, or any other geometrical shape.

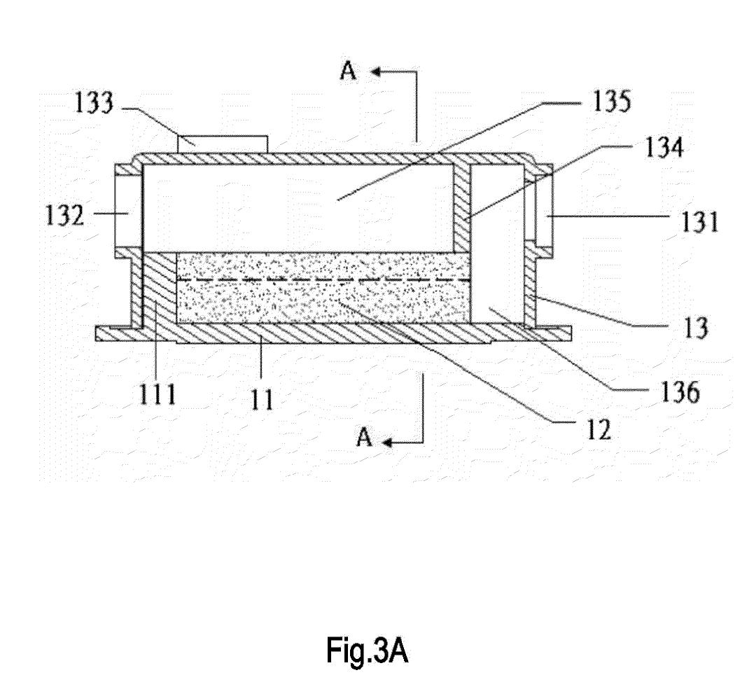

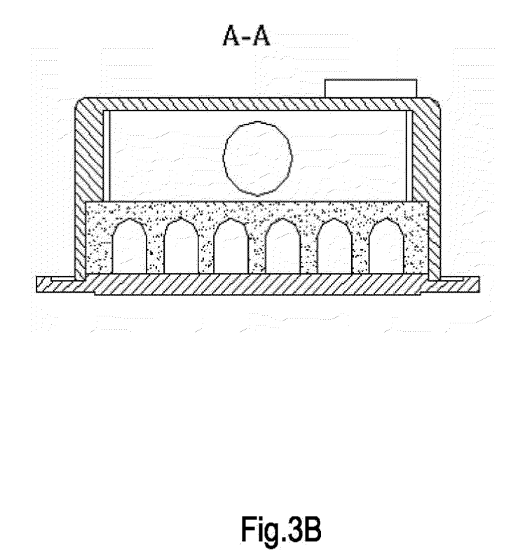

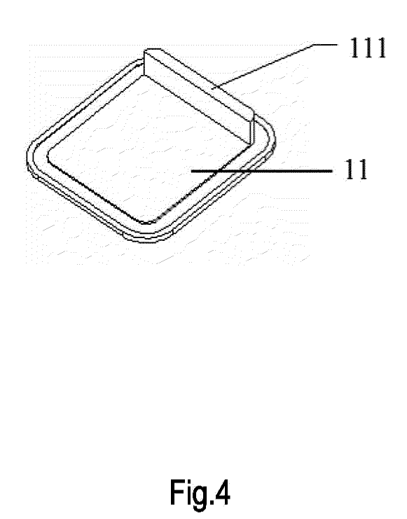

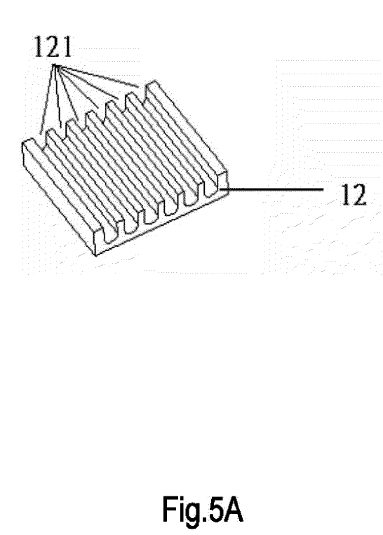

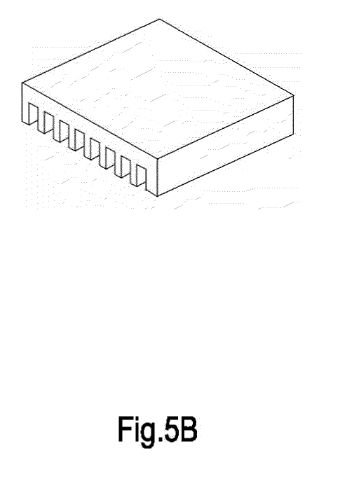

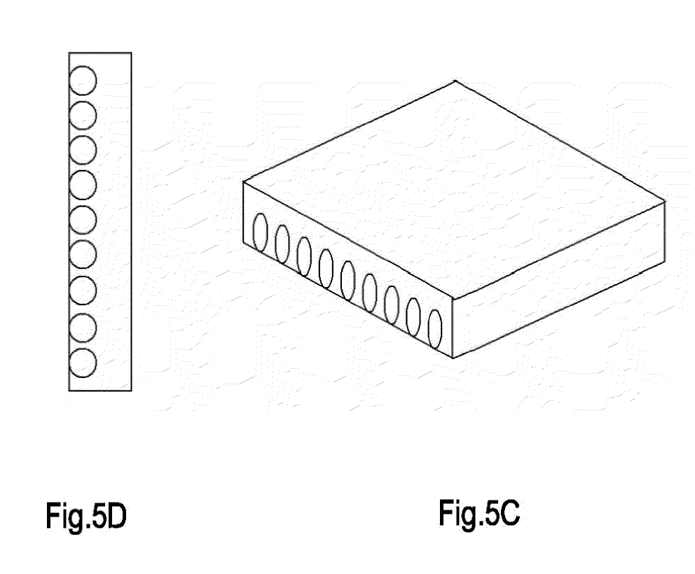

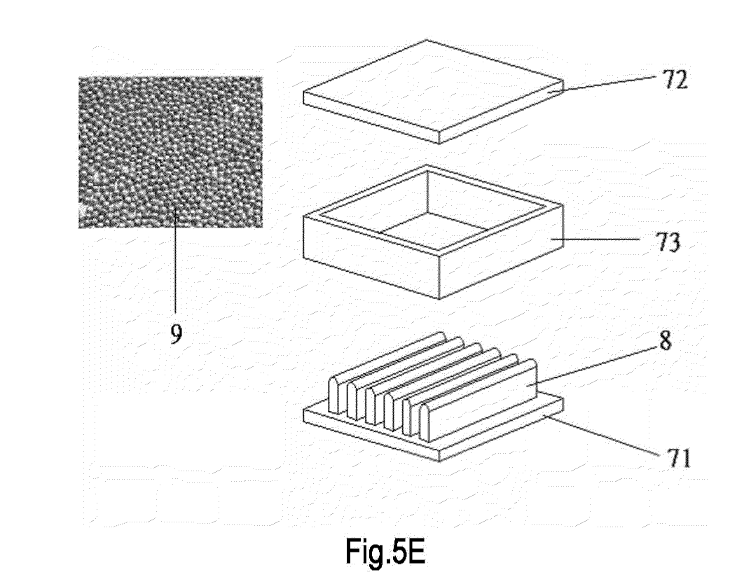

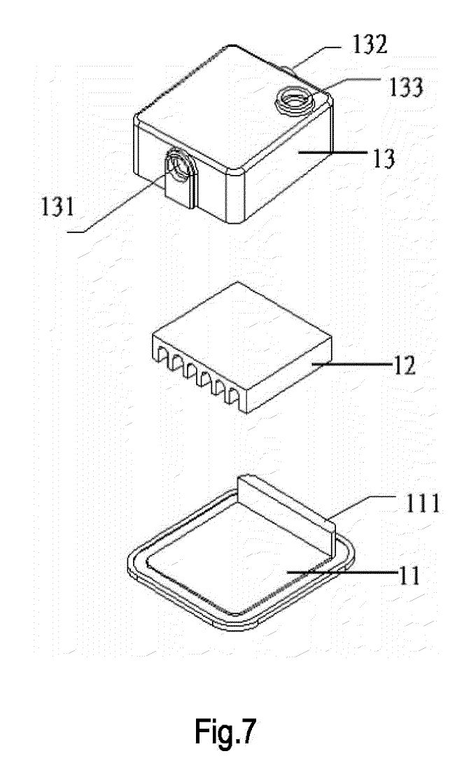

Please refer to FIGS. 3A, 3B, and 7. The flat evaporator 1 includes a main body consisting of a bottom plate 11, a porous material 12, and a top lid 13. The porous material 12 is located in a receiving space defined between the bottom plate 11 and the top lid 13 of the main body. The main body is provided at two opposite sides with a port each, namely, a vapor port 131 and a liquid port 132. Please refer to FIG. 4. The bottom plate 11 has a flat bottom face (not shown) for bearing on an electronic chip. The bottom plate 11 is provided on a top face with a raised portion 111, which can have different sectional shapes, such as a hook shape, a needle shape, an anchor shape, or other geometrical shapes. The raised portion 111 serves as a fixture to help in locating the porous material 12 in place when it is desired to directly sinter the porous material 12 on the bottom plate 11. As can be seen in FIGS. 3A and 3B, the porous material 12 is disposed on the top of the bottom plate 11. The porous material 12 can be formed from metal powder or metal mesh with high heat conductivity, such as copper powder. Alternatively, the porous material 12 can be formed from other inorganic materials, such as ceramic powder and the like. Oh the porous material 12, there are formed a plurality of vapor flow passages 121, through which vapor can flow. The vapor flow passage 121 can have differently formed cross sectional shapes. FIG. 5A shows a plurality of arch-sectioned vapor flow passages 121, FIG. 5B shows a plurality of rectangular-sectioned vapor flow passages 121, FIG. 5C shows a plurality of oval-sectioned vapor flow passages 121, and FIG. 5D shows a plurality of circular-sectioned or quasi-circular-sectioned vapor flow passages 121. Or, the vapor flow passages 121 can have a honeycombed cross section, a polygonal cross section, or a cross section of any other geometrical shape (not shown).

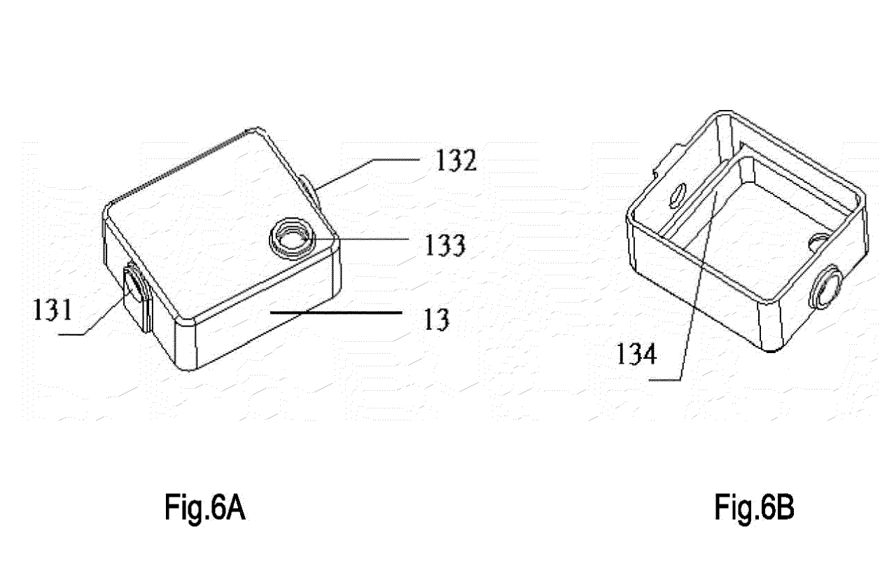

FIGS. 6A and 6B are top and bottom perspective views, respectively, of the top lid 13 for the flat evaporator 1. As shown, the top lid 13 is provided at an inner side with a partition 134 and at a top with a port 133, via which the flat evaporator 1 can be evacuated and a working medium can be filled into the flat evaporator 1. A duct is connected at an end to the port 133 and at the ether end to a vacuum pump and a working medium reservoir. After the working medium has been completely filled into the flat evaporator 1 and the heat dissipating device has internally reached at a required level of vacuum, the duct is sealed and cut, and the cut end is welded, as shown, in FIG. 2. Since the duct does not exist, on a finished product, it is not shown in FIG. 6A and 6B. Since the actual procedures of filling a working medium info a heat pipe or similar products have been described in many related textbooks or reference documents, they are not discussed in details herein. The top lid 13 is also provided at two opposite sides with a vapor port 131 and a liquid port 132. As can be seen from FIG. 3A, a compensating chamber 135 is formed between the partition 134 and the liquid port 132, and a vapor collecting chamber 136 is formed between the partition 134 and the vapor port 131. The partition 134 isolates the compensating chamber 135 from the vapor collecting chamber 136, so that the working medium roan flow inside the flat evaporator 1 only in one direction. The vapor pipe 2 has two ends separately connected to the vapor port 131 on the top lid 13 of the flat evaporator 1 and one side of the condenser 4; and the liquid pipe 3 has two ends separately connected to the liquid port 132 on the top lid 13 of the flat evaporator 1 and another side of the condenser 4.

The heat dissipating device according to the present invention is manufactured according to the following steps:
(1) Prepare the porous material 12. The porous material 12 can be prepared using metal powder or metal mesh with high heat conductivity, such as copper powder. Alternatively, the porous material 12 can be prepared using other inorganic materials, such as ceramic powder and the like. As shown in FIG. 5A, the porous material 12 is provided with a plurality of vapor flow passages 121, through which vapor can flow. In the case the porous materiel 12 is prepared using metal powder; the porous material 12 can be independently sintered or directly sintered on the bottom plate 11. During sintering, a special tool and a plurality of core rods 8 are required to form the vapor flow passages 121. The tools and core rods 8 can be made of high-temperature graphite, high-temperature ceramic material, carbon steel, or the like. The porous material 12 can also be prepared through microelectronic processing technology, such as porous silicon. Moreover, the porous material 12 can also be prepared using nanorods. Therefore, all these types of porous materials are included in the scope and spirit of the present invention to be protected. Please refer to FIG. 5E, which shows an example of forming the porous material 12. First, assemble the tools and the core rods 8 together. The tool includes a lower plate 71, an upper plate 72, and a middle frame 73. The lower plate 71 and the core rods 8 can be integrally formed to omit other special locating structures. Then, a powder material 9 is uniformly fed into the tool and the upper plate 72 is smoothly positioned on a top of the frame 73, so that the powder material 9 can be filled in a whole chamber defined in the tool. Finally, as in the process for forming a general sintered heat pipe, the whole tool is positioned in a sintering furnace and sintered, so that the powder material 9 is molded. Then, the tool and the core rods 8 are removed to complete the preparation of the porous material 12. The porous material 12 can also be prepared through microelectronic processing technology. For example, the porous material 12 can also be prepared using a porous semiconductor material through standard etching technology, or using nanorods through standard glancing-angle deposition.
(2) Prepare the top lid 13. The top lid 13 can be made of a copper material, an aluminum material, or a semiconductor material. In the case of preparing the top lid 13 using a metal material, the top lid 13 can be formed through mechanical machining, or through press casting and followed by mechanical machining. In the case of preparing the top lid 13 with a semiconductor material, the top lid 13 can be formed through microelectronic processing.
(3) Prepare the bottom plate 11. The bottom plate 11 can be prepared by mechanically machining, stamping, or casting a material with, high heat conductivity, such as copper, aluminum, or silicon. Or, the bottom plate 11 can be otherwise prepared through microelectronic processing.

The top lid 13 and the bottom plate 11 of the flat evaporator 1 can be made of the same material, such as copper or aluminum; or be made of different materials, such as an aluminum top lid 13 and a copper bottom plate 11.
(4) Connect the top lid 13 to the bottom, plate 11. When the preparation of the porous material 12 is completed, the top lid 13 and the bottom plate 11 are connected to each other to complete the flat evaporator 1. In the case the top lid 13 and the bottom plate 11 are made (c)f a metal material, such as copper, they can be connected together by soldering, brazing, or diffusion bonding. Or, in the case the top lid 13 and the bottom plate 11 are made of a semiconductor material, such as silicon, they can be connected together through bonding.
(5) Complete the heat dissipating device. Weld the finished flat evaporator 1 to the vapor pipe 2 and liquid pipe 3 that are extended through the condenser 4; and then, carry on standard heat pipe forming procedures, including cleaning the pipe, evacuating the pipe, filling a working medium into the pipe, and sealing the pipe. At this point, a heat dissipating device, having a Loop heat pipe provided with a flat evaporator according to the present invention is completed.

The condenser 4 and the vapor and liquid pipes 2, 3 are commercially available components.

When the heat dissipating device of the present invention operates, the bottom plate 11 of the flat evaporator 1 receives heat transferred from a heat-producing element in contact with the bottom plate 11, so that the working medium is heated and vaporized in the flat evaporator 1. The vapor leaves the flat evaporator 1 to flow through the curved vapor pipe 2 to the condenser 4, which has a plurality of fins. When flowing through the condenser 4, the vapor releases heat to environmental media that flow through the condenser 4, such as air. Through natural cooling or forced cooling by the cooling fan 5, the vapor is converted into liquid, which will return to the flat evaporator 1 via the liquid pipe 3 due to a capillary action provided by the porous; material 12 in the flat evaporator 1 to thereby complete one thermodynamic cycle. The above operation is repeated to constantly release heat from the heat-producing element into ambient air.

The heat dissipating device of the present invention can be used to dissipate heat produced by computer chips, including central processing unit (GPU) and graphics processing unit (GPU). The present invention can also be used to cool light-emitting diode (LED) illuminating devices, as well as high-power electronic chips, photoelectric chips, or radio-frequency integrated circuit (RFIC) for wireless or wired communication products. Meanwhile, the present invention can be applied in the cooling of high-power heat-producing components in military radar, laser apparatus, medical instruments or aerial and aerospace apparatus.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat dissipating device, comprising at least an evaporator, a vapor pipe, a liquid pipe, and a condenser; the evaporator being a flat evaporator including a main body and at least a porous material; the main body internally defining a receiving space for receiving the porous material therein, and being provided at two opposite sides with a port each; the two ports being respectively connected to an end of the vapor pipe and the liquid pipe; and the porous material having a plurality of vapor flow passages formed thereon.

2. The feat dissipating device as claimed in claim 1, wherein the main body of the evaporator includes a top lid and a bottom plate.

3. The heat dissipating device as claimed in claim 2, wherein the bottom plate has a flat bottom face for correspondingly bearing on an electronic chip.

4. The heat dissipating device as claimed in claim 2, wherein the bottom plate is provided on a top face with a raised portion for holding the porous material in place on the bottom plate.

5. The heat dissipating device as claimed in claim 1, wherein the ports provided on the two opposite sides of the main body are a vapor port and a liquid port.

6. The heat dissipating device as claimed in claim 1, further comprising a coding fan mounted to one side face of the condenser.

7. The heat dissipating device as claimed in claim 2, wherein the top lid is internally provided with a partition, such that a compensating chamber is formed between the partition and the port connecting to the liquid pipe, and a vapor collecting chamber is formed between the partition and the port connecting to the vapor pipe; and the partition isolating the compensating chamber from the vapor collecting chamber.

8. The heat dissipating device as claimed in claim 5, wherein the top lid is internally provided with a partition, such that a compensating chamber is formed between the partition and the liquid port, and a vapor collecting chamber is formed between the partition and the vapor port; and the partition isolating the compensating chamber from the vapor collecting chamber.

9. The heat dissipating device as claimed in claim 7, wherein the top lid is provided at a location above the compensating chamber in the evaporator with a port, via which the evaporator can be evacuated and a working medium can be filled into the evaporator.

10. The heat dissipating device as claimed in claim 8, wherein the top lid is provided at a location above the compensating chamber in the evaporator with a port, via which the evaporator can be evacuated and a working medium can be filled into the evaporator.

11. The heat dissipating device as claimed in claim 1, wherein the flat evaporator can have an external configuration selected from the group consisting of a rectangular shape, a polygonal shape, and any other geometrical shape.

12. The heat dissipating device as claimed in claim 1, wherein the vapor flow passage can have a cross-sectional shape selected from the group consisting of an arch shape, a rectangular shape, a quasi-circular shape, a honeycomb shape, a polygonal shape, and any other geometrical shape.

13. A method, of manufacturing the heat dissipating device being claimed in claim 1, comprising the following steps:
(a) preparing the porous material using metal powder with high heat conductivity or ceramic powder; wherein, in the ease of preparing the porous material using metal powder, the metal powder is either independently sintered or directly sintered on the bottom plate; and wherein, before the sintering process, a special tool and a plurality of core rods are prepared, the sinter metal powder being filled in the special tool that has an internal chamber configured corresponding to a desired external geometrical configuration of the porous material, end the core rode each being configured, corresponding to a desired cross sectional shape of the vapor flow passages on the porous material and being connected to the special tool for cooperatively forming the porous material with desired vapor flow passages; then, positioning the whole tool filled with the sinter metal powder in a sintering furnace; and, after the sintering process, removing the tool and the core rods to obtain the finished porous material;
(b) preparing the top lid using a metal material or a semiconductor material; wherein, in the case of preparing the top lid with a metal material, the top lid is formed through mechanical machining, or through press casting and followed by mechanical machining; and wherein, in the case of preparing the top lid with a semiconductor material, the top lid is formed through microelectronic processing;
(c) preparing the bottom plate by mechanically machining, stamping, or casting a material with high heat conductivity, such as copper, aluminum, or silicon; or preparing the bottom plate by performing microelectronic processing on a semiconductor material;
(d) connecting the top lid to the bottom plate when the preparation of the porous material is completed, so as to complete the evaporator; wherein, in the case of having, metal-made top lid and bottom plate, the top lid and the bottom plate are connected together by soldering or brazing; and wherein, in the case of having top lid and bottom plate made of a semiconductor material, the top lid and bottom plate are connected together through bonding; and
(e) welding the finished flat evaporator to the pipes that are extended through the condenser; and carrying on standard heat pipe forming procedures, including pipe cleaning, pipe evacuating, filling of working medium into pipe, and pipe sealing, so as to complete the heat dissipating device having a loop heat pipe provided with a flat evaporator.

14. The heat dissipating device manufacturing method as claimed in claim 13, wherein, in the step of preparing the porous material, the porous material can be otherwise made of a metal mesh material.

15. The heat dissipating device manufacturing method as claimed in claim 13, wherein, in the step of preparing the porous material, the porous material can be otherwise prepared by performing microelectronic processing on a semiconductor material, or be prepared using nanorods.

16. The heat dissipating device manufacturing method as claimed in claim 13, wherein, in the step of preparing the porous material, during the sintering process, the tool and the core rods used to form the vapor flow passages are made of a material selected from the group consisting of high-temperature graphite, high-temperature ceramic material, and carbon steel.

17. The heat dissipating device manufacturing method as claimed in claim 13, wherein, when both the top lid and the bottom plate are made of a metal material, the top lid and the bottom plate can be made of the same metal material or be made of different metal materials.

18. The heat dissipating device manufacturing method as claimed in claim 15, wherein, in preparing the porous material by performing the microelectronic processing technology on a semiconductor material, a porous semiconductor material is etched through standard etching technology; and wherein, in preparing the porous material using nanorods, the nanorods are processed through standard glancing-angle deposition to obtain the porous material with required structure.
